(19) United States
(12) Patent Application Publication
(10) Pub. No.: US 2018/0321874 A1
(43) Pub. Date: Nov. 8, 2018

(54) FLASH MANAGEMENT OPTIMIZATION FOR DATA UPDATE WITH SMALL BLOCK SIZES FOR WRITE AMPLIFICATION MITIGATION AND FAULT TOLERANCE ENHANCEMENT

(71) Applicant: Alibaba Group Holding Limited, George Town (KY)

(72) Inventors: Shu Li, Bothell, WA (US); Xiaowei Jiang, San Mateo, CA (US); Fei Liu, Fremont, CA (US)

(21) Appl. No.: 15/585,499

(22) Filed: May 3, 2017

(51) Int. Cl. G06F 3/06; G06F 11/10; G11C 29/52

(52) U.S. Cl. CPC G06F 3/0659; G06F 3/0616; G11C 29/52; G06F 11/1068; G06F 3/064

(57) ABSTRACT

One or more write requests which include a plurality of logical data chunks are received. The plurality of logical data chunks are distributed to a plurality of physical pages on Flash such that data from different logical data chunks are stored in different ones of the plurality of physical pages, wherein a logical data chunk is smaller in size than a physical page.

### BACKGROUND OF THE INVENTION

Tunnel injection and tunnel release are respectively used to program and erase NAND Flash storage. Both types of operations are stressful to NAND Flash cells, causing the electrical insulation of NAND Flash cells to break down over time (e.g., the NAND Flash cells become “leaky” which is bad for data which is stored for a long time period of time). For this reason, it is generally desirable to keep the number of program and erase cycles down. New techniques for managing NAND Flash storage which reduce the total number of programs and erases would be desirable.

### BRIEF DESCRIPTION OF THE DRAWINGS

Various embodiments of the invention are disclosed in the following detailed description and the accompanying drawings.

FIG. 1 is a flowchart illustrating an embodiment of a process to store logical data chunks in Flash.

FIG. 2 is a diagram illustrating an embodiment of data chunks stored on different physical pages in the same block on the same NAND Flash integrated circuit (IC).

FIG. 3 is a diagram illustrating an embodiment of data chunks stored on different physical pages on different blocks on different NAND Flash integrated circuits (IC).

FIG. 4 is a flowchart illustrating an embodiment of a process to store a modified version of a logical data chunk.

FIG. 5 is a diagram illustrating an embodiment of modified versions to logical data chunks stored in the same physical page as previous versions.

FIG. 6 is a diagram illustrating an embodiment of updates to a Flash translation layer and write pointer.

FIG. 7 is a flowchart illustrating an embodiment of a process to distribute logical data chunks amongst a plurality of physical pages for those logical data chunks which do not exceed a size threshold.

FIG. 8 is a flowchart illustrating an embodiment of a process to use a trial version of a logical data chunk to assist in error correction decoding.

FIG. 9A is a diagram illustrating an embodiment of a trial version of a logical data chunk used to assist in error correction decoding.

FIG. 9B is a diagram illustrating an embodiment of a fragment in a window which is ignored when calculating a similarity measure and generating a trial version.

FIG. 10A is a flowchart illustrating an embodiment of a process to obtain a trial version of a logical data chunk.

FIG. 10B is a flowchart illustrating an embodiment of a process to obtain a trial version of a logical data chunk while discounting fragments which are suspected to be updates.

FIG. 11 is a flowchart illustrating an embodiment of a relocation process.

FIG. 12 is a diagram illustrating an embodiment of logical data blocks which are divided into a first group and a second group using a write pointer position threshold.

FIG. 13 is a diagram illustrating an embodiment of logical data blocks which are divided into a first group and a second group using a percentile cutoff.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

Various embodiments of a NAND Flash storage system which reduces the number of programs and/or erases are described herein. First, some examples of previous and modified versions of logical data chunks stored in NAND Flash are discussed. Then, some examples of how the various versions of the logical data chunks may be used to assist in error correction decoding are described. Finally, some examples of a relocation process (e.g., to consolidate the information stored in the NAND Flash and/or free up blocks) are described.

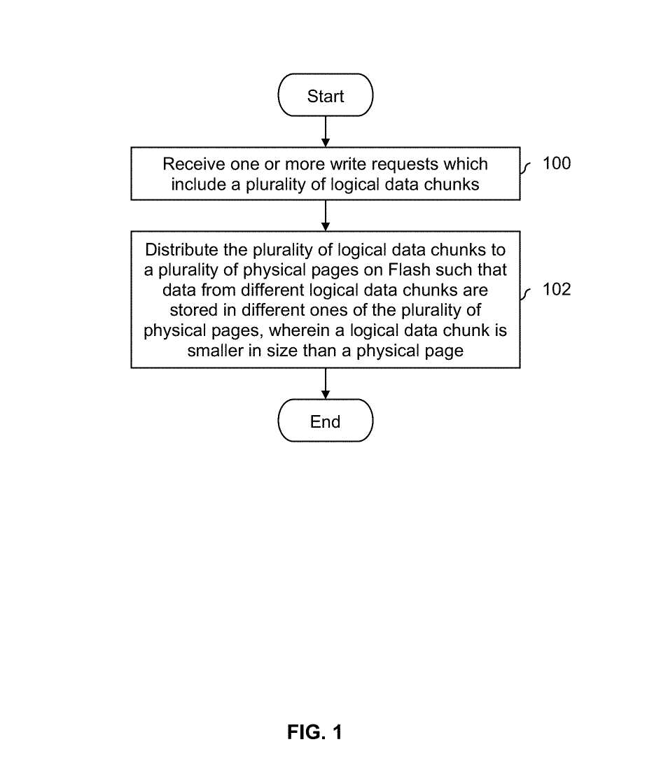

FIG. 1 is a flowchart illustrating an embodiment of a process to store logical data chunks in Flash. In some embodiments, the process is performed by a Flash controller which controls access (e.g., reading from and writing to) one or more Flash integrated circuits. In some embodiments, the Flash includes NAND Flash.

At 100, one or more write requests which include a plurality of logical data chunks are received. In some cases, the logical data chunks which are received at step 100 are all associated with or part of the same write request. Alternatively, each of the logical data chunks may be associated with its own write request. In some embodiments, the write request(s) is/are received from a host.

At 102, the plurality of logical data chunks are distributed to a plurality of physical pages on Flash such that data from different logical data chunks are stored in different ones of the plurality of physical pages, wherein a logical data chunk is smaller in size than a physical page. For example, by storing each logical data chunk on its own physical page, subsequent updates of those logical data chunk result in fewer total programs and/or erases. In some embodiments, the logical data chunks are distributed to physical pages on different blocks and/or different (e.g., NAND) Flash integrated circuits. Alternatively, the logical data chunks may be distributed to physical pages on the same block and/or same (e.g., NAND) Flash integrated circuit.

In one example, the NAND Flash is used in a hyperscale data center which runs many applications. At least some of those applications have random writes with a relatively small block size (e.g., 512 Bytes) where the small blocks or chunks are updated frequently. This disclosure presents the novel scheme to mitigate the write amplification from the small-chunk of data which is frequently updated.

The following figures show some examples of how the plurality of logical data chunks are distributed to a plurality of physical pages.

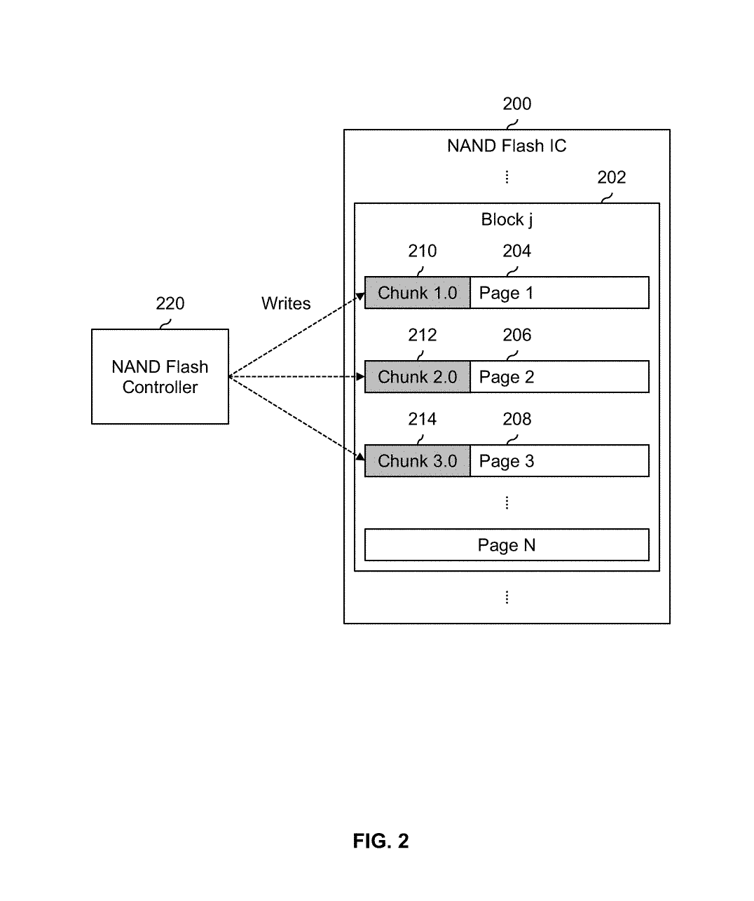

FIG. 2 is a diagram illustrating an embodiment of data chunks stored on different physical pages in the same block on the same NAND Flash integrated circuit (IC). This figure shows one example of step 102 in FIG. 1.

In the example shown, NAND Flash integrated circuit (IC) 200 includes multiple blocks, including block j (202). Each block, including block j (202), includes multiple physical pages such as physical page 1 (204), physical page 2 (206), and physical page 3 (208).

In this example, three logical data chunks are received: chunk 1.0 (210), chunk 2.0 (212), and chunk 3.0 (214). These are examples of logical data chunks which are received at step 100 in FIG. 1. Chunk 1.0 (210), chunk 2.0 (212), and chunk 3.0 (214) are stored respectively on physical page 1 (204), physical page 2 (206), and physical page 3 (208) in this example.

In contrast, some other storage system may choose to group the chunks together and store all of them on the same physical page. For example, some other storage systems may choose to append chunk 1.0, chunk 2.0, and chunk 3.0 to each other (not shown) and store them on the same physical page. As will be described in more detail below, when updates to chunk 1.0, chunk 2.0, and/or chunk 3.0 are subsequently received, the total numbers of programs and erases is greater (i.e., worse) when the exemplary chunks are stored on the same physical page compared to when they are stored on different physical pages (one example of which is shown here).

In this example, the three chunks (210, 212, and 214) are written to NAND Flash IC 200 by NAND Flash controller 220. NAND Flash controller 220 is one example of a component which performs the process of FIG. 1.

The following figure shows another example where chunks are stored on different physical pages but those pages are in different blocks and different NAND Flash integrated circuits.

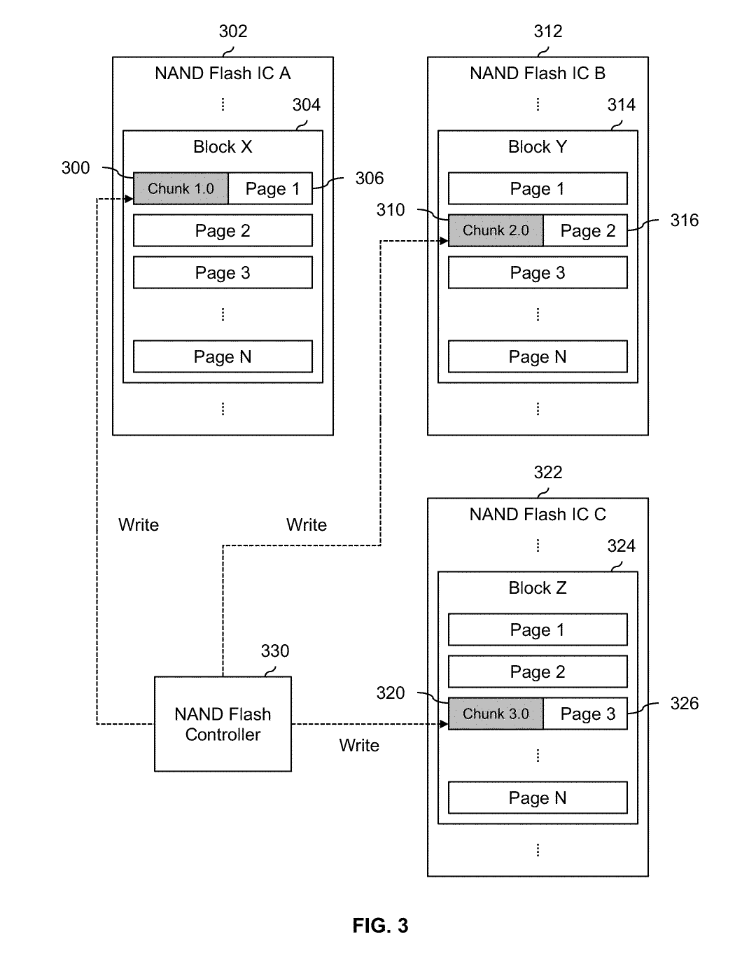

FIG. 3 is a diagram illustrating an embodiment of data chunks stored on different physical pages on different blocks on different NAND Flash integrated circuits (IC). This figure shows another storage arrangement of blocks and illustrates another example of step 102 in FIG. 1.

As before, three logical data chunks have been received and are to be stored in this example. The chunk 1.0 (300) is stored on NAND Flash integrated circuit A (302) in block X (304) in page 1 (306). The chunk 2.0 (310) is stored on NAND Flash integrated circuit B (312) in block Y (314) in page 2 (316). The chunk 3.0 (320) is stored on NAND Flash integrated circuit C (322) in block Z (324) in page 3 (326).

Like the previous example, the three chunks are stored on different physical pages. Unlike the previous example, however, the three chunks are stored on different NAND Flash integrated circuits and in different blocks (e.g., with different block numbers). FIG. 2 and FIG. 3 are merely exemplary and chunks may be distributed across different physical pages in a variety of ways.

The writes of the chunks (300, 310, and 320) to the pages, blocks and NAND Flash integrated circuits shown here is performed by NAND Flash controller 330, which is one example of a component which performs the process of FIG. 1.

The following figures discuss examples of how logical data chunks are updated.

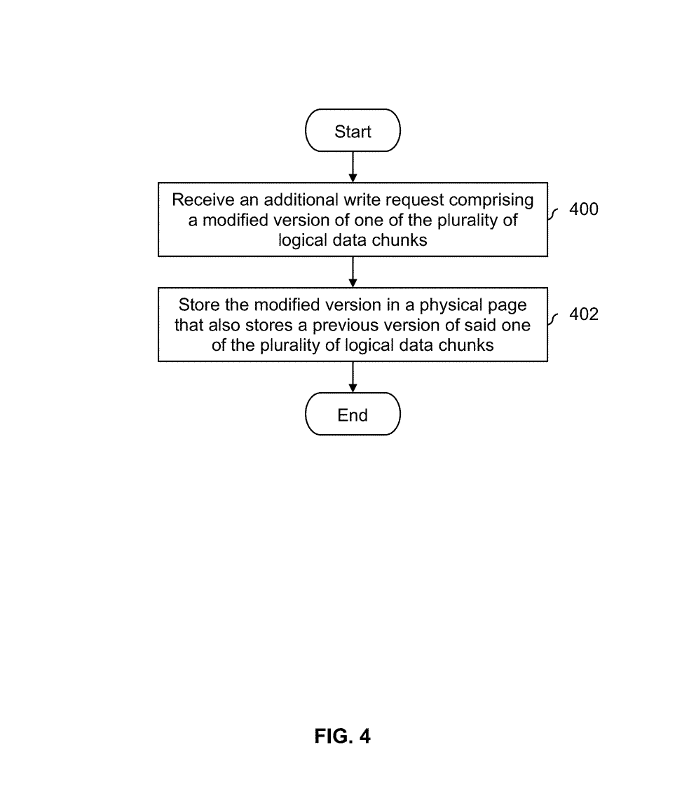

FIG. 4 is a flowchart illustrating an embodiment of a process to store a modified version of a logical data chunk. In some embodiments, the process of FIG. 4 is performed in combination with the process of FIG. 1 (e.g., the process of FIG. 1 is used to store an initial version of a logical data chunk, such as chunk 1.0, and the process of FIG. 4 is used to store a modified version of the logical data chunk, such as chunk 1.1). In some embodiments, the process of FIG. 4 is performed by a NAND Flash controller.

At 400, an additional write request comprising a modified version of one of the plurality of logical data chunks is received. For example, suppose the write request at received step 100 in FIG. 1 identified some logical block address to be written. At step 400, the same logical block address would be received but with (presumably) different write data.

At 402, the modified version is stored in a physical page that also stores a previous version of said one of the plurality of logical data chunks. For example, assuming space on the physical page permits, the modified version is written next to the previous version (i.e., on the same physical page as the previous version).

The following figure describes an example of this.

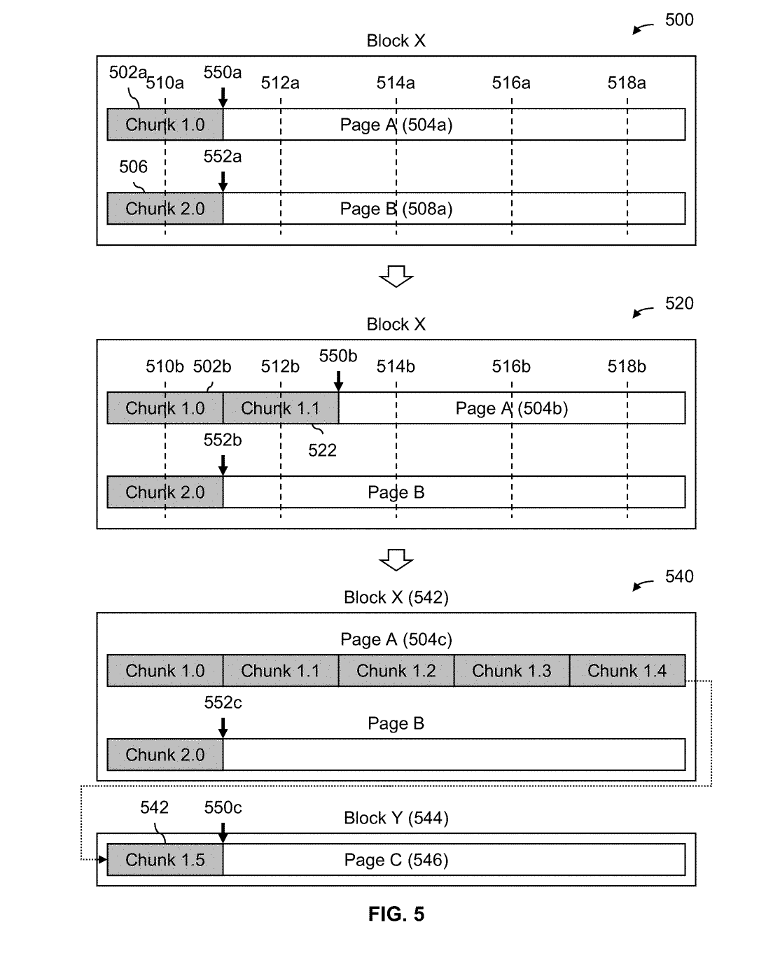

FIG. 5 is a diagram illustrating an embodiment of modified versions to logical data chunks stored in the same physical page as previous versions. In the example shown, diagram 500 shows two pages (i.e., page A (504a) and page B (508a) at a first point in time where the two pages are in the same block (i.e., Block X). In the state shown in diagram 500, a first version of first logical data chunk (i.e., chunk 1.0 (502a) is stored on page A (504a), and a first version of a second logical data chunk (i.e., chunk 2.0 (506) is stored on page B (508a). Diagram 500 shows on example of the state of pages in NAND Flash storage after the process of FIG. 1 is performed, but before the process of FIG. 4 is performed.

When writing to NAND Flash, pages are typically written as a whole. However, during write operation, each bitline has its own program and verify check. When one cell reaches its expected programmed state, this bitline is shut down, and no further program pulse will be applied onto this cell (i.e., no more charge will be added to that cell). The other cells in this page that have not reached their expected states will continue the program and verify check until the cell's threshold voltage reaches the individual, desired charge level. In some embodiments, only part of a page is programmed by turning off other bitlines (e.g., to only program the chunk 2.0). The physics are not novel. For convenience and brevity, a single bitline is shown for each chunk but a single bitline may actually correspond to a single cell.

Diagram 520 shows the same pages at a second point in time after a second (i.e., updated) version of the first chunk is received and stored. In this example, chunk 1.1 (522) is stored next to chunk 1.0 (502b) in page A (504b) because chunk 1.1 is an updated version of chunk 1.0 which replaces chunk 1.0. To write chunk 1.1 (522) to page A (504b), the second-from-left bitline (512b) is selected. The other bitlines (i.e., bitlines 510b, 514b, 516b, ad 518b) are not selected since nothing is being written to those locations at this time.

In some embodiments, a NAND Flash controller or other entity performing the process of FIG. 4 knows that chunk 1.1 corresponds to chunk 1.0 because a logical block address included in a write request for chunk 1.1 is the same logical block address included in a write request for chunk 1.0. The use of the same logical block address indicates that chunk 1.1 is an updated version of chunk 1.0.

In some embodiments, a NAND Flash controller knows where to write chunk 1.1 in page A because each physical page has a write pointer (shown with arrows) that tracks the last chunk written to that page and thus where the next chunk should be written. Chunk 1.1 (522) is one example of a modified version of a logical data chunk which is received at step 400 in FIG. 4 and the storage location of chunk 1.1 (522) shown here is one example of storing at step 402 in FIG. 4.

One reason why distributing logical data chunks across different physical pages (e.g., per FIG. 1) is attractive is because no other chunks need to be read back and re-written when another chunk is updated. For example, suppose that chunk 1.0 and chunk 2.0 had instead initially been grouped together and stored in the same physical page (e.g., both on page A where for simplicity page A is entirely filled by the two chunks) per some other storage/update technique. If so, then the entire page would be read back to obtain chunk 1.0 and chunk 2.0. Chunk 1.0 would be swapped out and chunk 1.1 would be put in its place (i.e., at the same location within the page). Then, the new page with chunk 1.1 and chunk 2.0 would be written back to the page in question (e.g., page A).

Write amplification is the amount of data written to the NAND Flash divided by the amount of data written by a host or other upper-level entity. If chunk 1.0 and chunk 2.0 were stored together on the same physical page (as described above), then the write amplification for updating chunk 1.0 to be chunk 1.1 would be 2/1=2 since the host writes or otherwise updates chunk 1.1 (i.e., 1 chunk of data) but what is actually written to the NAND Flash is chunk 1.1 and chunk 2.0 (i.e., 2 chunks of data).

In contrast, the write amplification associated with diagram 520 is 1/1=1. This is because the host writes chunk 1.1 (i.e., 1 chunk of data) and the actual amount of data written to the NAND Flash is chunk 1.1 (i.e., 1 chunk of data). For example, this may be enabled by selecting appropriate bitlines (e.g., corresponding to the (next) empty space in the page after to the previous version).

Keeping the write amplification performance metric down is desirable because extra writes to the NAND Flash delay the system's response time to instructions from the host. Also, as described above, programs (i.e., writes) gradually damage the NAND Flash over time and it is desirable to minimize the number of writes to the NAND Flash to a minimum. For these reasons, it is desirable to keep write amplification down.

Diagram 540 shows the pages at a third point in time. In the state shown, page A (504c) has been filled with different versions of the first chunk (i.e., chunk 1.0-1.4) and is now full. The most recent version of chunk 1.X (i.e., chunk 1.5 (542)) is written to a new physical page because page A is full. In this example, the new page (i.e., page C (546)) is specifically selected to be part of a new or different block (i.e., block Y (544) instead of block X (542)). This is because garbage collection (e.g., a process to copy out any remaining valid data and erase any stored information in order to free up space) is performed at the block level. By writing chunk 1.5 to a new or different block (in this example, block Y (544)), block X (542) can more quickly be garbage collected.

Another benefit to this technique is that there are fewer updates to the Flash translation layer which stores logical to physical mapping information. The following figure illustrates an example of this.

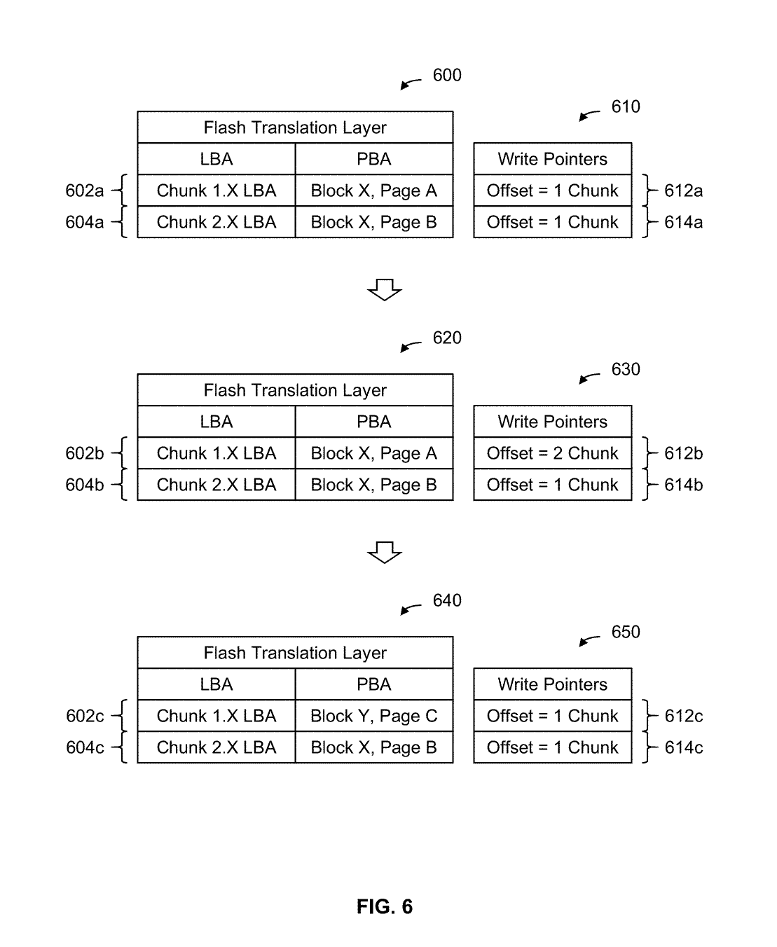

FIG. 6 is a diagram illustrating an embodiment of updates to a Flash translation layer and write pointer. Table 600 shows the Flash translation layer (FTL) in a state which corresponds to diagram 500 in FIG. 5. The FTL stores the mapping between logical block addresses (LBA) and physical block addresses (PBA). Row 602a shows the mapping information for chunk 1.0 (502a) in FIG. 5: the LBA is the LBA which corresponds to chunk 1.X (i.e., all chunks 1.X use the same LBA) and the PBA indicates that chunk 1.0 is stored in block X, on page A (see diagram 500 in FIG. 5).

Row 604a in table 600 shows the mapping information for chunk 2.0 (506) in diagram 500 in FIG. 5: the LBA is the LBA which corresponds to all chunks 2.X and the PBA indicates that chunk 2.0 is stored in block X, on page B (see diagram 500 in FIG. 5). In some embodiments, the PBA also includes a NAND Flash IC on which the logical data chunk in question is stored.

Table 610 also corresponds to diagram 500 in FIG. 5 and shows the write pointers. The write pointers are used to track the end of written data in each page. When a new modified version of a chunk is received, it is known where to write that next version within the page. In this example, the write pointers are tracked by their offset within the page. As shown, row 612a is used to record that the write pointer for chunk 1.X (currently chunk 1.0) is at an offset of 1 chunk (see write pointer 550a in FIG. 5) and row 614a is used to record that the write pointer for chunk 2.X (currently chunk 2.0) is also at an offset of 1 chunk (see write pointer 552a in FIG. 5).

Table 620 and table 630 correspond to diagram 520 in FIG. 5. Note that even though there is a new chunk 1.1 (522) in diagram 520 in FIG. 5, the mapping information in row 602b and row 604b are the same as in row 602a and 604a, respectively, because the LBA information and PBA information have not changed. In other words, the FTL does not need to be updated. And even though the respective write pointer is modified with each update, updating a write pointer may be faster and/or consume less resources than updating the FTL because entries in the write pointers are smaller than entries in the FTL.

Table 630 shows the write pointers updated to reflect the new position of the write pointer for chunk 1.X (now chunk 1.1). Row 612b, for example, notes that the write pointer for chunk 1.X is located at an offset of 2 chunks. See, for example, write pointer 550b in FIG. 5. Row 614b has not changed because the write pointer for chunk 2.X has not moved. See, for example, write pointer 552b in FIG. 5.

Table 620 and table 630 correspond to diagram 540 in FIG. 5. The PBA information in row 602c has been updated to reflect that the most recent chunk 1.X (now chunk 1.5) is stored in block Y, on page C (see chunk 1.5 (542) in FIG. 5). This corresponds to a new write pointer offset of 1 chunk which is stored in (see write pointer 550c in FIG. 5). There is no updated chunk 2.X and the mapping information in row 604c and the write pointer information in row 614c remain the same.

As shown here, it is not until the page is completely filled that the FTL information for a particular chunk (in this example, chunk 1.X) is updated. In this example where 5 chunks fit into a page, the FTL information is updated ⅕^{th} the number of times the FTL information used to be updated.

The benefits associated with the storage technique described herein tend to be most apparent when the chunks are relatively small. In some embodiments, the process of FIG. 1 is performed only for those chunks which do not exceed some length or size threshold. The following figure illustrates an example of this.

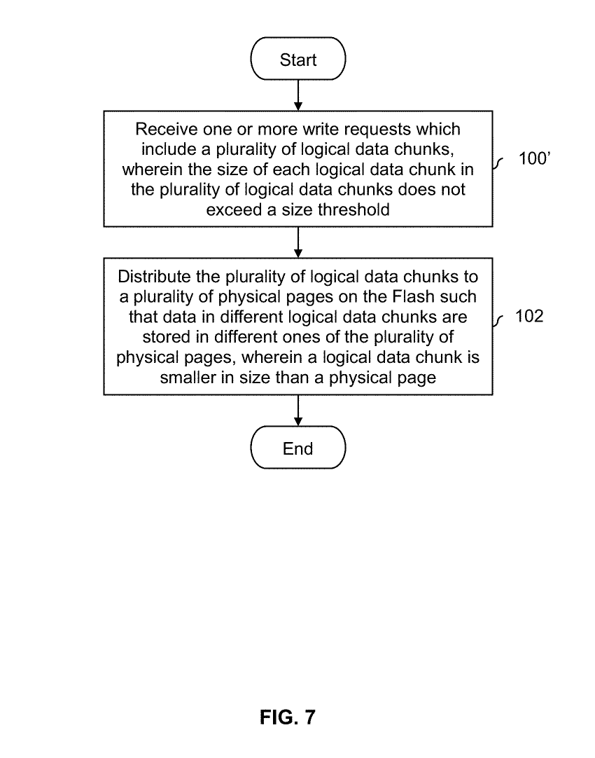

FIG. 7 is a flowchart illustrating an embodiment of a process to distribute logical data chunks amongst a plurality of physical pages for those logical data chunks which do not exceed a size threshold. The process of FIG. 7 is similar to the process of FIG. 1 and similar reference numbers are used to show related steps.

At 100′, one or more write requests which include a plurality of logical data chunks are received, wherein the size of each logical data chunk in the plurality of logical data chunks does not exceed a size threshold. For example, prior to step 100′, the logical data chunks may be pre-screened by comparing the size of the logical data chunks against some size threshold and therefore all logical data chunks that make it to step 100's are less than some size threshold.

At 102, the plurality of logical data chunks are distributed to a plurality of physical pages on the Flash such that data from different logical data chunks are stored in different ones of the plurality of physical pages, wherein a logical data chunk is smaller in size than a physical page.

To illustrate what might happen to logical data chunks which do exceed the size threshold, in one example those larger chunks are grouped or otherwise aggregated together and written to the same physical page. This is merely exemplary and other storage techniques for larger chunks may be used.

In one example, the size of a physical page is 16 or 32 kB but the NAND Flash storage system is used with a file system (e.g., ext4) which uses 512 Bytes as the size of a logical block address. In one example, logical data chunks which are 512 Bytes or smaller are distributed to a plurality of physical pages where each page is 16 or 32 kB. This size threshold is merely exemplary and is not intended to be limiting.

Since older copies of a given logical data chunk are not overwritten until the block is erased, one or more previous versions of the logical data chunk may be used to assist in error correction decoding when decoding fails (e.g., for the most recent version of that logical data chunk). The following figures describe some examples of this.

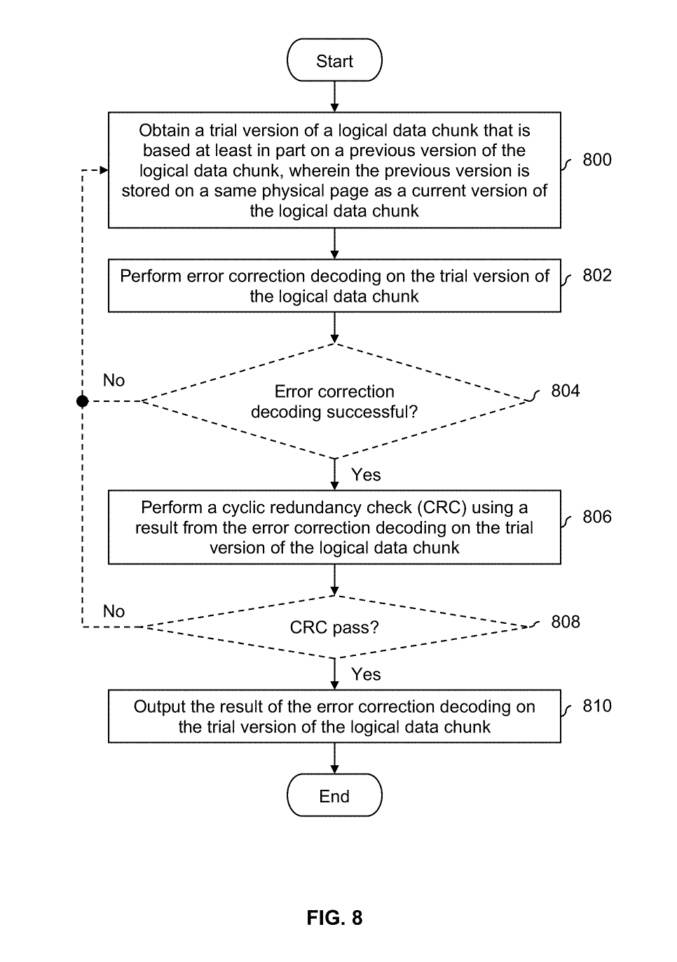

FIG. 8 is a flowchart illustrating an embodiment of a process to use a trial version of a logical data chunk to assist in error correction decoding. In some embodiments, the process of FIG. 8 is performed by a NAND Flash controller (e.g., NAND Flash controller 220 in FIG. 2 or NAND Flash controller 330 in FIG. 3).

At 800, a trial version of a logical data chunk is obtained that is based at least in part on a previous version of the logical data chunk, wherein the previous version is stored on a same physical page as a current version of the logical data chunk. For example, supposed chunk 1.0, chunk 1.1, and chunk 1.2 are all different version of the same logical data chunk from oldest to most recent. In one example described below, chunk 1.1 (one example of a previous version) and chunk 1.2 (one example of a current version) are stored on the same physical page. As will be described in more detail below, the trial version is generated by copying parts of chunk 1.1 into the trial version.

At 802, error correction decoding is performed on the trial version of the logical data chunk. Conceptually, the idea behind a trial version is to use a previous version to (e.g., hopefully) reduce the number of errors in the failing/current version to be within the error correction capability of the code. For example, suppose that the code can correct (at most) n errors in the data and CRC portions. If there are (n+1) errors in the current version, then error correction decoding will fail. By generating a trial version using parts of the previous version, it is hoped that the number of errors in the trial version will be reduced so that it is within the error correction capability of the code (e.g., reduce the number of errors to n errors or (n−1) errors, which the decoding would then be able to fix). That is, it is hoped that copying part(s) of the previous version into the trial version eliminates at least one existing error and does not introduce new errors.

At 804, it is checked whether error correction decoding is successful. If so, a cyclic redundancy check (CRC) is performed using a result from the error correction decoding on the trial version of the logical data chunk at 806. For example, there is the possibility of a false positive decoding scenario where decoding is successful (e.g., at step 802 and 804) but the decoder output or result does not match the original data. To identify such false positives, a CRC is used.

After the performing the cyclic redundancy check at step 806, it is checked whether the CRC passes at 808. For example, all versions of the logical data block include a CRC which is based on the corresponding original data. If the CRC output by the decoder (e.g., at step 804) matches the data output by the decoder (e.g., at step 804), then the CRC is declared to pass.

If the CRC passes at step 808, then the result of the error correction decoding on the trial version of the logical data chunk is output at 810. A trial version may fail to produce the original data for a variety of reasons (e.g., copying part of the previous version does not remove existing errors, copying part of the previous version introduces new errors, decoding produces a result which satisfies the error correction decoding process but which is not the original data, etc.), and therefore the decoding result is only output if error correction decoding succeeds and the CRC check passes.

If decoding is not successful at step 804, then a next trial version is obtained at step 800. For example, a different previous version of the logical data chunk may be used. In some embodiments, the process ends if the check at step 804 fails more than a certain number of time.

If the CRC does not pass at step 808, then a next trial version is obtained at step 800. As described above, multiple tries and/or trial versions may be attempted before the process decides to quit.

In some embodiments, the process of FIG. 8 is performed in the event error correction decoding fails (e.g., on the current version of a logical data chunk). That is, the process of FIG. 8 may be used as a secondary or backup decoding technique. In some embodiments, if the process of FIG. 8 fails (e.g., after repeated attempts using a variety of trial versions), then system-level protection is used to recover the data (e.g., obtaining a duplicate copy stored elsewhere, using RAID to recover the data, etc.). In some embodiments, the process shown in FIG. 8 runs until a timeout occurs, at which point the data is recovered using system-level protection.

In order to have a convenient fork or branch point, steps 804 and step 808 are included in FIG. 8 but the amount of decision making and/or processing associated with those steps is relatively trivial. For this reason, those steps are shown with a dashed outline in FIG. 8.

It may be helpful to illustrate the process of FIG. 8 using exemplary data. The following figure illustrates one such example.

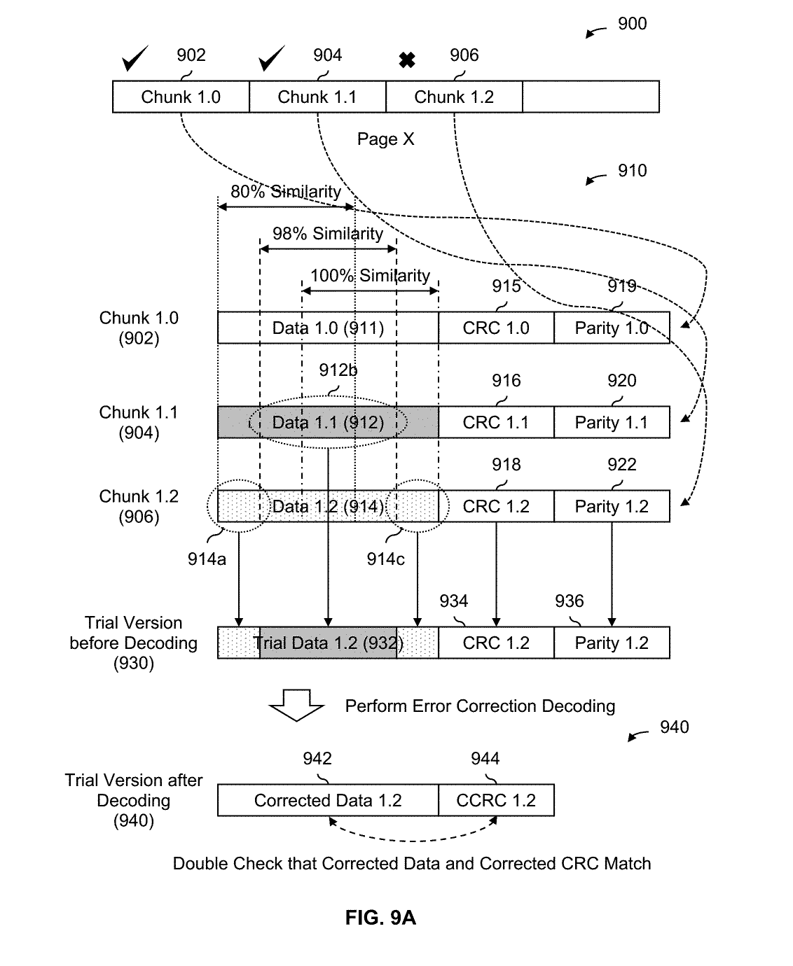

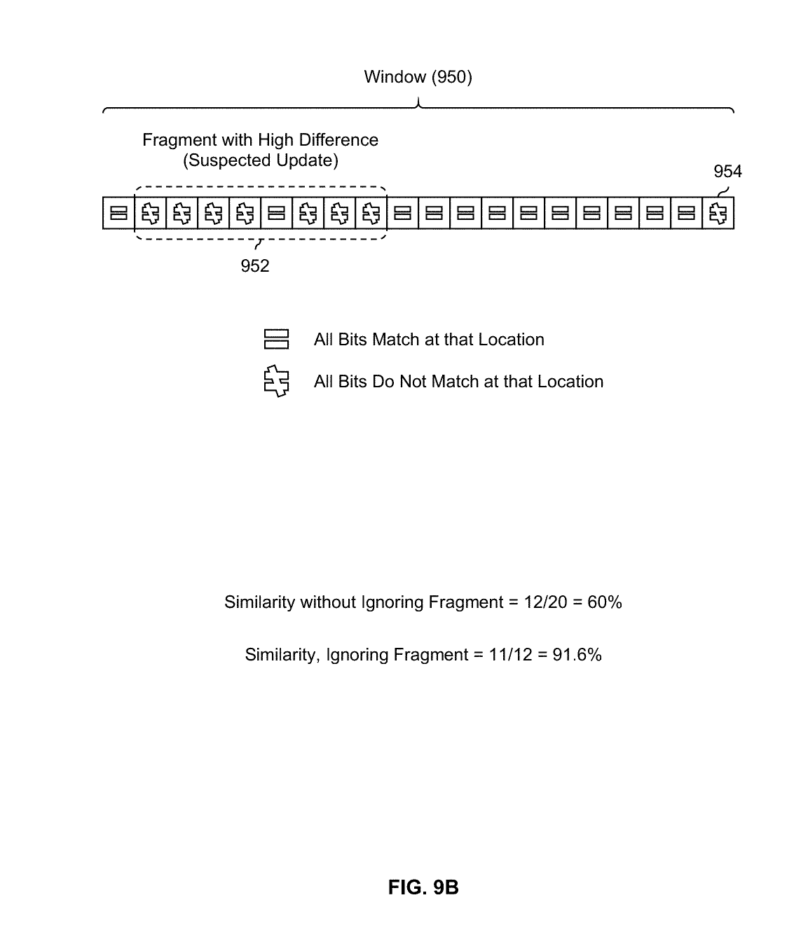

FIG. 9A is a diagram illustrating an embodiment of a trial version of a logical data chunk used to assist in error correction decoding. In the example shown, diagram 900 shows three chunks on the same physical page: chunk 1.0 (902), chunk 1.1. (904), and chunk 1.2 (906). The three chunks shown are different versions of the same logical data chunk where chunk 1.0 is the initial and oldest version, chunk 1.1 is the second oldest version, and chunk 1.2 is the most recent version. Chunk 1.0 and chunk 1.1 have sufficiently few errors and pass error correction decoding (note the check marks above chunk 1.0 and chunk 1.1). Chunk 1.2, on the other hand, has too many errors and these errors exceed the error correction capability of the code and error correction decoding fails (note the “X” mark above chunk 1.2).

A trial version of the logical data chunk (which is based on a previous version of the logical data chunk) is used to assist with decoding because error correction decoding for chunk 1.2 has failed. Diagram 910 shows an example of how the trial version (930) may be generated. In this example, chunk 1.0 (902) and chunk 1.1 (904) are the previous versions of the logical data chunk which are used to generate the trial version. In some embodiments, the two most recent versions of the logical data chunk which passes error correction decoding are used to generate the trial version. Using two or more previous versions (as opposed to a single previous version) may be desirable because if the current version (e.g., chunk 1.2) and single previous version do not match, it may be difficult to decide if it is a genuine change to the data or an error.

In this example, the chunks contain three portions: a data portion (e.g., data 1.0 (911), data 1.1 (912), and data 1.2 (914)) which contains the payload data, a cyclic redundancy check (CRC) portion which is generated from a corresponding data portion (e.g., CRC 1.0 (915) which is based on data 1.0 (911), CRC 1.1 (916) which is based on data 1.1 (912), and CRC 1.2 (918) which is based on data 1.2 (914)), and a parity portion which is generated from a corresponding data portion and a corresponding CRC portion (e.g., parity 1.0 (919) which is based on data 1.0 (910) and CRC 1.0 (915), parity 1.1 (920) which is based on data 1.1 (912) and CRC 1.1 (916), and parity 1.2 (922) which is based on data 1.2 (914) and CRC 1.2 (918)).

The data portions (i.e., data 1.0 (911), data 1.1 (912), and data 1.2 (914)) are compared using a sliding window (e.g., where the length of the sliding window is shorter than the length of the data portion) to obtain similarity values for each of the comparisons. For brevity, only three comparisons are shown here: a comparison of the beginning of the data portions, a comparison of the middle of the data portions, and comparison of the end of the data portions. These comparisons yield exemplary similarity values of 80%, 98%, and 100%, respectively. For example, each time all of the corresponding bits are the same, it counts toward the similarity value and each time the corresponding bits do not match (e.g., one of them does not match the other two), it counts against the similarity value.

In some embodiments, the length of a window is relatively long (e.g., 50 bytes) where the total length of the data portion is orders of magnitude larger (e.g., 2 KB). Comparing larger windows and setting a relatively high similarity threshold (e.g., 80% or higher) may better identify windows where any difference between the current version and the previous version is due to errors and not due to some update of the data between versions.

The similarity values (which in this example are 80%, 98%, and 100%) are compared to a similarity threshold (e.g., 80%) in order to identify windows which are highly similar but not identical. In this example, that means identifying those similarity values which are greater than or equal to 80% similar but strictly less than 100% similar. The similarity values which meet this division criteria are the 80% and 98% similarity values which correspond respectively to the beginning window and middle window. Therefore, two trial versions may be generated: one using the beginning window and one using the middle window.

Trial version 930 (i.e., before decoding) shows one example of a trial version which is obtained at step 800 in FIG. 8 and which is generated from the middle window with 98% similarity. In this example, this trial version would be attempted first (i.e., it would be input to an error correction decoder first before a trail version generated from the beginning portion) because it is the most similar. Using the window with the highest similarity (i.e., fewest differences) first may reduce the likelihood of introducing any new errors into the trial version. As with the other chunks, the trial version before error correction decoding (930) has three portions: a data portion (932), a CRC portion (934), and a parity portion (936). The CRC portion (934) and parity portion (936) of the trial version are obtained by copying the CRC portion and parity portion from the version which failed error correction decoding (in this example, CRC 1.2 (918) and parity 1.2 (922) from chunk 1.2 (906)).

The data portion (932) is generated using that part of the previous version which is highly similar to (but not identical to) the current version which failed error correction decoding. In this example, that means copying the middle part of data 1.1 (912b) to be the middle part of trial data 1.2 (932). The beginning part of trial data 1.2 (932) is obtained by copying the beginning part of data 1.2 (914a) and the end a part of trial data 1.2 (932) is obtained by copying the beginning part of data 1.2 (914c).

Copying part of a previous version into a trial version is conceptually the same thing as guessing or hypothesizing about the location of error(s) in the current version and attempting to fix those error(s). For example, if a window of the current version is 0000 and is 1000 in the previous version, then copying 1000 into the trial version is the same thing as guessing that the first bit is an error and fixing it (e.g., by flipping that first bit, 0000→1000).

Error correction decoding is then performed on the trial version (930) which produces a trial version after decoding (940). This is one example of the error correction decoding performed at step 802 in FIG. 8. In this example, decoding is assumed to be successful. The trial version (940) includes corrected data 1.2 (942) and a corrected CRC (CCRC) 1.2 (944). The parity portion is no longer of interest and is not shown here.

To ensure that the error correction decoding process decoded or otherwise mapped trial data 1.2 (932) to the proper corrected data 1.2 (942) (that is, the corrected data matches the original data), a double check is performed using the corrected data (942) and corrected CRC (944) to ensure that they match. This is one example of step 806 in FIG. 8. If the CRC check passes (e.g., corrected data (942) and corrected CRC (944) correspond to each other) then the corrected data is output (e.g., to an upper-level host). This is one example of step 810 in FIG. 8.

In some embodiments, multiple trial versions are tested where the various trial versions use various windows and/or various previous versions copied into them (e.g., because trial versions continue to be tested until one passes both error correction decoding and the CRC check). In some embodiments, if there are multiple trial versions, the one with the highest similarity measurement is tested first. For example, if the trial version generated from the middle window with 98% similarity (930) had failed error correction decoding and/or the CRC check, then a trial version generated from the beginning window with 80% similarity (not shown) may be put through error correction decoding and the CRC check next.

In some embodiments, a fragment in a window (e.g., within the 80%, 98%, or 100% similar windows shown here) is ignored when calculating a similarity value and/or generating a trial version. The following figure shows one example of this.

FIG. 9B is a diagram illustrating an embodiment of a fragment in a window which is ignored when calculating a similarity measure and generating a trial version. In the example shown, a similarity value is being calculated for the window (950) shown. In the example of FIG. 9A, two previous versions (which passed error correction decoding) and a current version (which failed error correction decoding) are compared using three windows. Within the window, there is a fragment (952) with a high amount or degree of difference (e.g., the amount of difference exceeds some threshold). That fragment may correspond to an update, for example if the bit sequence 00000000 were updated to become 11110111.

If a similarity value is calculated without ignoring the fragment, then the similarity value is 12/20 or 60%. If, however, the fragment is ignored, then the similarity value is 11/12 or 91.6%.

When generating the trial version, the fragment (952) would be ignored. For example, if the trial version is thought of as the current version with some bits flipped, then the trial version would be the current version flipped only at the last bit location (954) but the bits in the fragment (952) would not be flipped.

In some embodiments, fragments with high differences may be identified and ignored when calculating a similarity measurement because those fragments are suspected updates and are not errors. If a trial version is generated using this window, this would corresponding to not flipping the bits of the current version (which failed error correction decoding) at the bit locations corresponding to the fragment. In some embodiments, fragments always begin and end with a difference (e.g., shown here with a “≠”) and fragments are identified by starting at some beginning bit location (e.g., a difference) and adding adjacent bit locations (e.g., expanding leftwards or rightwards) so long as the difference value stays above some threshold (e.g., a fragment difference threshold). Once the difference value drops below that threshold, the end(s) may be trimmed to begin/end with a difference. For example, fragment 952 may be identified in this manner.

The following flowcharts more generally and/or formally describes the processes of generating a trial version shown there.

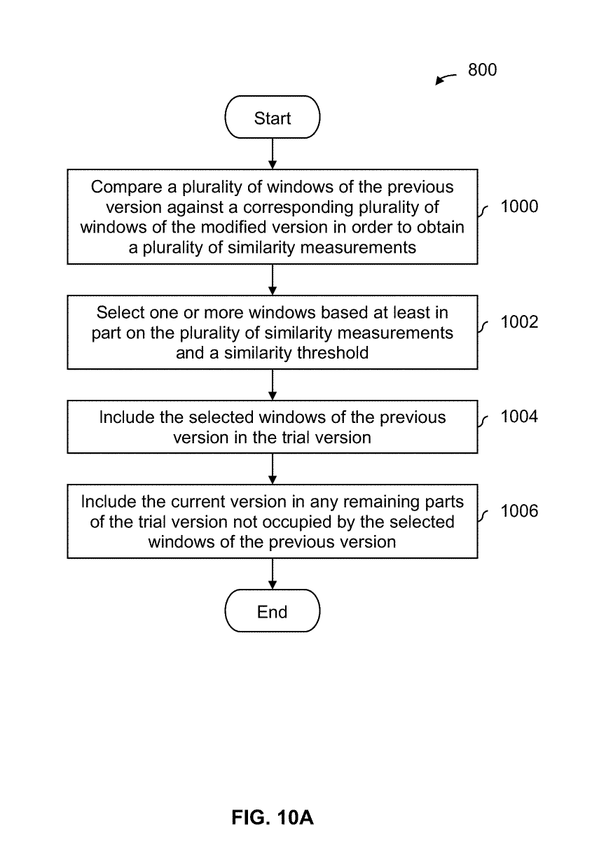

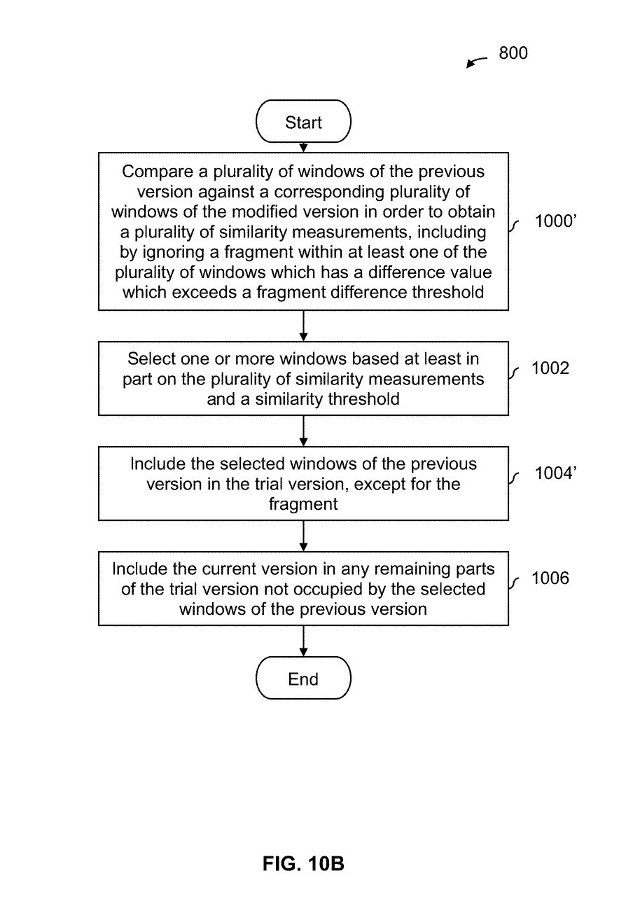

FIG. 10A is a flowchart illustrating an embodiment of a process to obtain a trial version of a logical data chunk. In some embodiments, the process of FIG. 10A is used at step 800 in FIG. 8.

At 1000, a plurality of windows of the previous version are compared against a corresponding plurality of windows of the modified version in order to obtain a plurality of similarity measurements. See, for example, the three windows in FIG. 9A which produce similarity measurements of 80%, 98%, and 100%.

At 1002, one or more windows are selected based at least in part on the plurality of similarity measurements and a similarity threshold. In some embodiments, only one window is selected and that window is the one with the highest similarity measurement that exceeds the similarity threshold but is not a perfect match. In some embodiments, multiple windows are selected (e.g., all windows that exceed a similarity threshold).

At 1004, the selected windows of the previous version are included in the trial version. For example, in FIG. 9A, the middle portion of data 1.1 (912b) is copied into the middle portion of trial data 1.2 (932).

At 1006, the current version is included in any remaining parts of the trial version not occupied by the selected windows of the previous version. In FIG. 9A, for example, the beginning part of data 1.2 (914a), the end part of data 1.2 (914c), CRC 1.2 (918), and parity 1.2 (922) are copied into corresponding locations in the trial version (930).

FIG. 10B is a flowchart illustrating an embodiment of a process to obtain a trial version of a logical data chunk while discounting fragments which are suspected to be updates. In some embodiments, the process of FIG. 10B is used at step 800 in FIG. 8. FIG. 10B is similar to FIG. 10A and similar reference numbers are used to show related steps.

At 1000′, a plurality of windows of the previous version are compared against a corresponding plurality of windows of the modified version in order to obtain a plurality of similarity measurements, including by ignoring a fragment within at least one of the plurality of windows which has a difference value which exceeds a fragment difference threshold. See, for example, fragment 952 in FIG. 9B.

At 1002, one or more windows are selected based at least in part on the plurality of similarity measurements and a similarity threshold.

At 1004′, the selected windows of the previous version are included in the trial version except for the fragment. As described above, this means using leaving those bits which fall into the fragment in the current version alone (i.e., not flipping them). Other bit locations outside of the fragment (e.g., isolated difference 954 in FIG. 9B) may be flipped (i.e., copied from a previous version).

At 1006, the current version is included in any remaining parts of the trial version not occupied by the selected windows of the previous version.

Returning to FIG. 5, it can be seen that distributing the plurality of logical data chunks amongst a plurality of physical pages may occasionally consume too much space. The following figures show some examples of a relocation process.

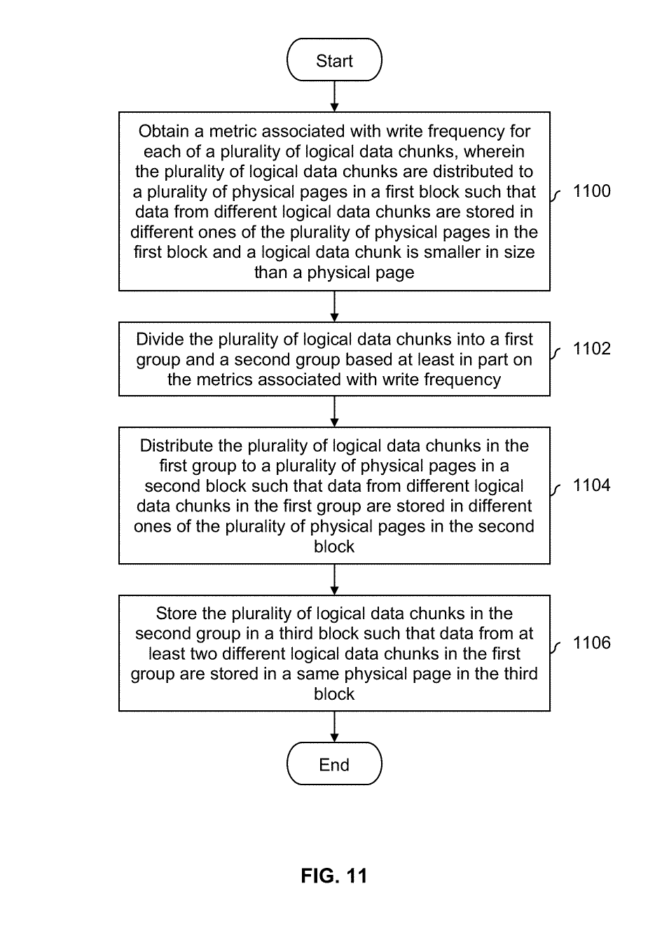

FIG. 11 is a flowchart illustrating an embodiment of a relocation process. In some embodiments, the exemplary relocation process is periodically run to consolidate logical data chunks and/or free up blocks. For example, the relocation process may input one set of blocks (e.g., source blocks) and relocate the logical data chunks (e.g., the most recent versions of those logical data chunks) contained therein to a second set of blocks (e.g., target blocks). After the relocation process has finished, garbage collection may be performed on the source blocks to erase the blocks and free them up for writing.

At 1100, a metric associated with write frequency is obtained for each of a plurality of logical data chunks, wherein the plurality of logical data chunks are distributed to a plurality of physical pages in a first block such that data from different logical data chunks are stored in different ones of the plurality of physical pages in the first block and a logical data chunk is smaller in size than a physical page. To put it another way, the first block is a source block which is input to the relocation process. Each of the logical data chunks in the plurality gets its own page (e.g., the various versions of a first logical data chunk (e.g., chunk 1.X) do not have to share the same physical page with the various versions of a second logical data chunk (e.g., chunk 2.X)).

At 1102, the plurality of logical data chunks are divided into a first group and a second group based at least in part on the metrics associated with write frequency. In some embodiments, division criteria used at step 1102 are adjusted until some desired relocation outcome is achieved. For example, the write frequency metrics may be compared against division criteria such as a write pointer position threshold or a percentile cutoff (e.g., associated with a distribution) at step 1102. If the desired relocation outcome is n total pages split amongst some number of shared pages (e.g., pages on which logical data chunks share a page) and some number of dedicated pages (e.g., pages on which logical data chunks have their own page), then the division criteria may be adjusted until the desired total number of pages (or, more generally, the desired relocation outcome) is reached.

At 1104, the plurality of logical data chunks in the first group are distributed to a plurality of physical pages in a second block such that data from different logical data chunks in the first group are stored in different ones of the plurality of physical pages in the second block. For example, the current version of the logical data chunks in the first group may be copied from the first block (i.e., a source block) into second block (i.e., a destination block) where each logical data chunk gets its own page in the second block.

At 1106, the plurality of logical data chunks in the second group are stored in a third block such that data from at least two different logical data chunks in the first group are stored in a same physical page in the third block. For example, the current version of the logical data chunks in the second group may be copied from the first block (i.e., a source block) to the third block (i.e., a destination block) where the logical data chunks share pages in the third block.

The following figures show some examples of this.

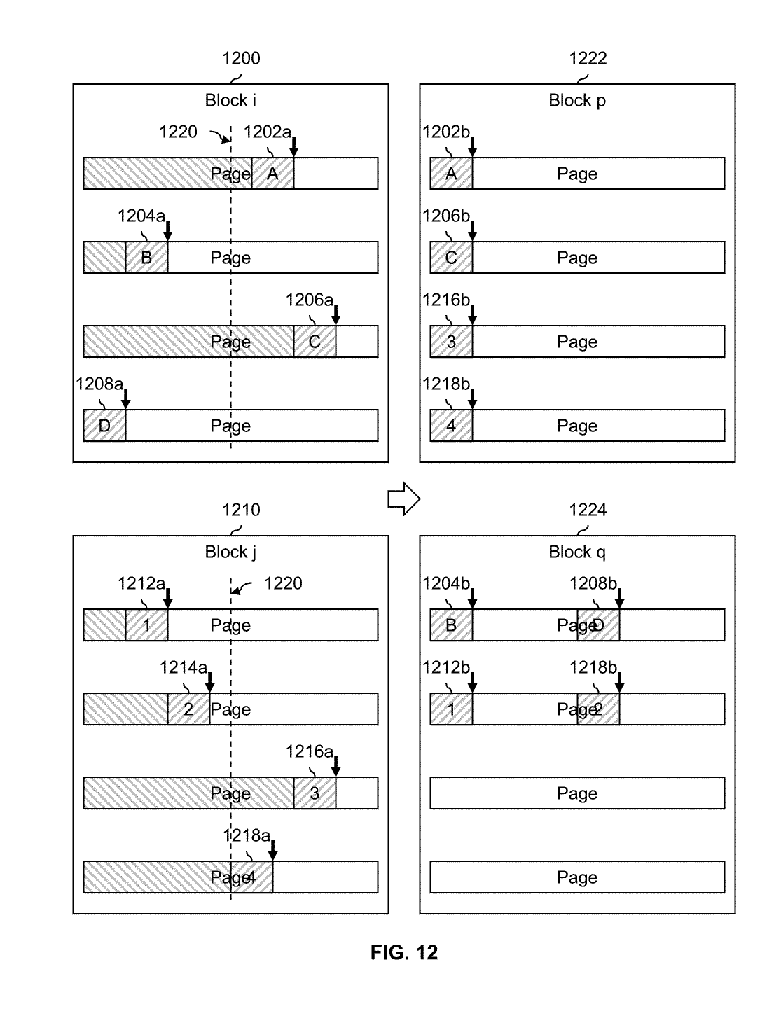

FIG. 12 is a diagram illustrating an embodiment of logical data blocks which are divided into a first group and a second group using a write pointer position threshold. In the example shown, block i (1200) and block j (1210) show the state of the system before the relocation process (described above in FIG. 11) is run. In this example, older versions of the various logical data chunks are shown with horizontal lines going from upper-left to lower-right. The current versions of the various logical data chunks are shown with horizontal lines going from lower-left to upper-right. The current versions are also identified by a letter (A-D in this example) or a number (1-4 in this example). Although older versions of the various logical data chunks are not identified by letter/number, it is to be understood that all of the versions in a same physical page in block 1200 and block 1200 relate to the same logical data chunks. For example, the process of FIG. 1 may have been used to place initial versions of the logical data chunks in blocks i and j and then the logical data chunks may have been updated using the process of FIG. 4.

In this example, the write pointers (shown as an arrow after each current version of each logical data chunk) are compared against a write pointer position threshold (1220). If the write pointer exceeds the threshold, then the current version of the corresponding logical data chunk is copied to block p (1222) where each logical data chunk gets its own physical page. For example, logical data chunks A (1202a), C (1206a), 3 (1216a), and 4 (1218a) meet this division criteria and are copied to block p where each gets its own page (see, e.g., how chunks A (1202b), C (1206b), 3 (1216b), and 4 (1218b) are on different physical pages by themselves). The older versions are not copied to block p in this example.

If a write pointer does not exceeds the threshold, then the current version of the corresponding logical data chunk is copied to block q (1224) where logical data chunks share physical pages. For example, logical data chunks B (1204a) and D (1208a) have write pointers which are less than the threshold (1200) and current versions of those logical data chunks are copied to the same physical page in block q (see chunk B (1204b) and chunk D (1208b)). Similarity, logical data chunks 1 (1212a) and 2 (1214a) have write pointers which do not exceed the threshold and current versions of those logical data chunks share the same physical page in block q (see chunk 1 (1212b) and chunk 2 (1214b)).

As described above, after relocation has completed, garbage collection (not shown) may be performed on block i (1200) and block j (1210).

As shown here, the relocation process divides the logical data chunks into two groups: more frequently updated chunks and less frequently updated chunks. During relocation, the more frequently updated chunks are given their own physical page. See, for example, block p (1222). The less frequently updated chunks share physical pages with other less frequently updated chunks. See, for example, block q (1224). This may be desirable for a number of reasons. For one thing, the more frequently updated chunks are given more space for updates (e.g., roughly an entire page of space for updates instead of roughly half a page of space of updates). Also, separating more frequently updated chunks from less frequently updated chunks may reduce write amplification and/or increase the number of free blocks available at any given time.

In some embodiments, the threshold (1220) is set or tuned to a value based on some desired relocation outcome. For example, if free blocks are at a premium and it would be desirable to pack the logical data chunks in more tightly, the threshold may be set to a higher value (e.g., so that fewer logical data chunks get their own physical page). That is, any threshold may be used and the value shown here is merely exemplary.

Referring back to FIG. 11, block i (1200) and block j (1210) show two examples of a first block (e.g., referred to in step 1100, on which the relocation process is run). Block p (1222) shows an example of a second block (e.g., referred to in step 1104, where each relocated logical data chunk gets its own physical page). Block q (1224) shows an example of a third block (e.g., referred to in step 1106, where relocated logical data chunks share physical pages). In other words, blocks i and j show examples of blocks which are input by a relocation process and blocks p and q show examples of blocks which are output by the relocation process.

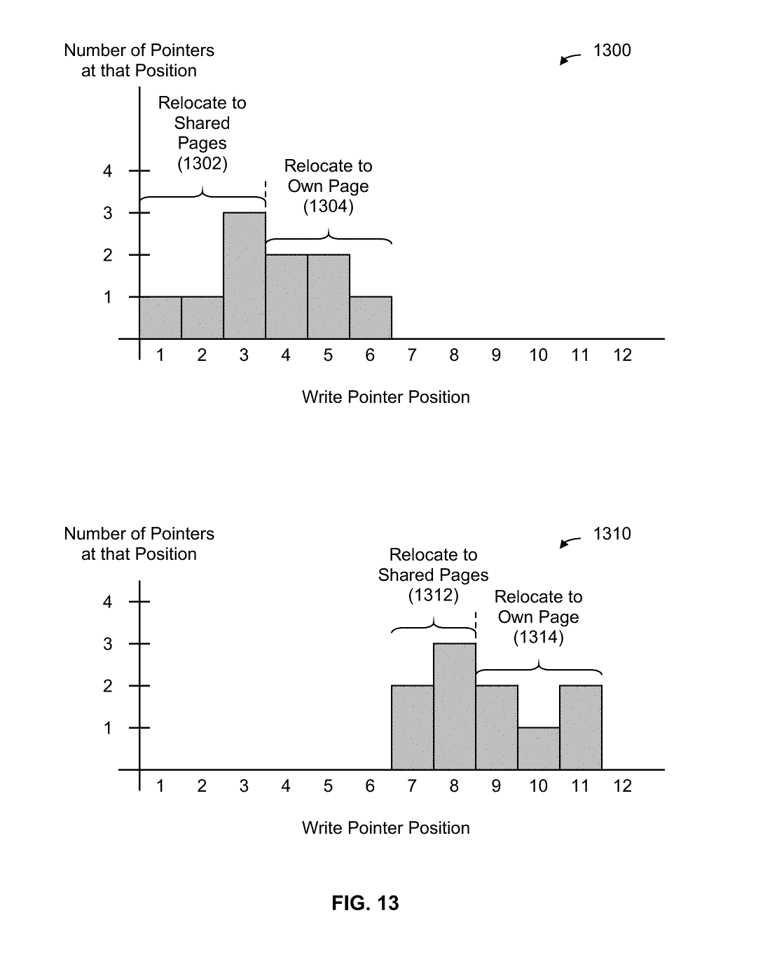

FIG. 13 is a diagram illustrating an embodiment of logical data blocks which are divided into a first group and a second group using a percentile cutoff. In the example shown, diagram 1300 shows a histogram associated with write pointer position. The x-axis shows the various write pointer positions and the y-axis shows the number of write pointers at a given write pointer position. In this example, logical data chunks in the bottom 50% of the distribution (1302) are relocated to shared pages where two or more logical data chunks share a single page. The logical data chunks in the upper 50% of the distribution (1304) are relocated to their own pages (i.e., those logical data chunks do not have to share a page).

Diagram 1310 shows this same process applied to a different distribution. Note, for example, that the shape of the distribution and the mean/median of the distribution are different. As before, logical data chunks in the bottom 50% of the distribution (1312) are relocated to shared pages and logical data chunks in the upper 50% of the distribution (1314) are relocated to their own pages.

As shown here, using or otherwise taking a distribution into account may be desirable because it is adaptive to various distributions. For example, if a write pointer position threshold of 6.5 had been used instead, then in the example of diagram 1300, all of the logical data chunks would be assigned to shared pages. In contrast, with a write pointer position threshold of 6.5 applied to diagram 1310, all of the logical data chunks would be assigned their own page.

Although a percentile cutoff of 50% is shown here, any percentile cutoff may be used.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A system, comprising:
a processor; and
a memory coupled with the processor, wherein the memory is configured to provide the processor with instructions which when executed cause the processor to:
receive one or more write requests which include a plurality of logical data chunks; and
distribute the plurality of logical data chunks to a plurality of physical pages on Flash such that data from different logical data chunks are stored in different ones of the plurality of physical pages, wherein a logical data chunk is smaller in size than a physical page.

2. The system recited in claim 1, wherein the Flash includes NAND Flash.

3. The system recited in claim 1, wherein the plurality of physical pages are in a same block.

4. The system recited in claim 1, wherein the plurality of physical pages are in a same Flash integrated circuit.

5. The system recited in claim 1, wherein the memory is further configured to provide the processor with instructions which when executed cause the processor to:
receive an additional write request comprising a modified version of one of the plurality of logical data chunks; and
store the modified version in a physical page that also stores a previous version of said one of the plurality of logical data chunks.

6. The system recited in claim 1, wherein the size of each logical data chunk in the plurality of logical data chunks does not exceed a size threshold.

7. A system, comprising:
a processor; and
a memory coupled with the processor, wherein the memory is configured to provide the processor with instructions which when executed cause the processor to:
obtain a trial version of a logical data chunk that is based at least in part on a previous version of the logical data chunk, wherein the previous version is stored on a same physical page as a current version of the logical data chunk;
perform error correction decoding on the trial version of the logical data chunk;
perform a cyclic redundancy check using a result from the error correction decoding on the trial version of the logical data chunk; and
output the result of the error correction decoding on the trial version of the logical data chunk.

8. The system recited in claim 7, wherein the cyclic redundancy check is performed in response to the error correction decoding being successful.

9. The system recited in claim 7, wherein the result is output in response to the cyclic redundancy check passing.

10. The system recited in claim 7, wherein the instructions for obtaining the trial version include instructions which when executed cause the processor to:
compare a plurality of windows of the previous version against a corresponding plurality of windows of the modified version in order to obtain a plurality of similarity measurements;
select one or more windows based at least in part on the plurality of similarity measurements and a similarity threshold;
include the selected windows of the previous version in the trial version; and
include the current version in any remaining parts of the trial version not occupied by the selected windows of the previous version.

11. The system recited in claim 7, wherein the instructions for obtaining the trial version include instructions which when executed cause the processor to:
compare a plurality of windows of the previous version against a corresponding plurality of windows of the modified version in order to obtain a plurality of similarity measurements, including by ignoring a fragment within at least one of the plurality of windows which has a difference value which exceeds a fragment difference threshold;
select one or more windows based at least in part on the plurality of similarity measurements and a similarity threshold;
include the selected windows of the previous version in the trial version, except for the fragment; and
include the current version in any remaining parts of the trial version not occupied by the selected windows of the previous version.

12. A system, comprising:
a processor; and
a memory coupled with the processor, wherein the memory is configured to provide the processor with instructions which when executed cause the processor to:
obtain a metric associated with write frequency for each of a plurality of logical data chunks, wherein the plurality of logical data chunks are distributed to a plurality of physical pages in a first block such that data from different logical data chunks are stored in different ones of the plurality of physical pages in the first block and a logical data chunk is smaller in size than a physical page;
divide the plurality of logical data chunks into at least a first group and a second group based at least in part on the metrics associated with write frequency;
distribute the plurality of logical data chunks in the first group to a plurality of physical pages in a second block such that data from different logical data chunks in the first group are stored in different ones of the plurality of physical pages in the second block; and
store the plurality of logical data chunks in the second group in a third block such that data from at least two different logical data chunks in the first group are stored in a same physical page in the third block.

13. The system recited in claim 12, wherein a write pointer position threshold is used to divide the plurality of logical data chunks into the first group and the second group.

14. The system recited in claim 12, wherein a percentile cutoff is used to divide the plurality of logical data chunks into the first group and the second group.

15. The system recited in claim 12, wherein the instructions for dividing the plurality of logical data chunks into the first group and the second group include instructions which when executed cause the processor to adjust one or more division criteria until one or more desired relocation outcomes are reached.

16. The system recited in claim 12, wherein the instructions for dividing the plurality of logical data chunks into the first group and the second group include instructions which when executed cause the processor to adjust one or more division criteria until one or more desired relocation outcomes are reached, including a desired total number of pages.
